(19) United States
(12) Patent Application Publication
(10) Pub. No.: US 2006/0040425 A1
(43) Pub. Date: Feb. 23, 2006

(54) Circuit element and method of manufacturing the same

(75) Inventor: Takahisa Tanabe, Tsurugashima-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION

(21) Appl. No.: 11/086,651

(22) Filed: Mar. 23, 2005

(30) Foreign Application Priority Data
Mar. 24, 2004 (JP) P2004-87542

(51) Int. Cl. H01L 21/48

(52) U.S. Cl. 438/108

(57) ABSTRACT

There is provided a circuit element using an organic semiconductor that maintains the characteristics of organic semiconductors in a stable manner for a long period, is highly durable against various kinds of stresses, impacts, etc. from outside and has excellent reliability. The circuit element comprises a circuit portion including an organic semiconductor formed on a substrate and a sealing can that envelopes the circuit portion with a prescribed space.

### BACKGROUND OF THE INVENTION

1. Field of the Invention

The present invention relates to a circuit element including, for example, a thin-film transistor (an organic TFT) using an organic semiconductor (an organic TFT) or the like and a method of manufacturing the circuit element or the like and, more particularly, to a technique for protecting the organic semiconductor or the like.

2. Description of the Related Art

In recent years, attention has been paid to circuit techniques that use the organic semiconductor thin-film transistor (organic TFT).

Application apparatuses and vacuum vapor deposition apparatuses used in the production of such organic TFTs are inexpensive compared to apparatuses such as CVD devices, sputter devices, etc., used in the production of general inorganic TFTs, for example, amorphous silicon TFTs. In addition, the film deposition temperature is lower in the former apparatuses than in the latter apparatuses and maintenance is also easy. Therefore, it is expected that organic TFTs can be supplied at lower prices than inorganic TFTs and the application to flexible substrates made of materials such as plastics can also be expected. This is the reason why organic TFTs have attracted attention.

Therefore, examinations are being made of the use of circuit elements using an organic semiconductor that is represented by an organic TFT in various semiconductor devices, such as displays, for example, an EL display, electronic tags and smart cards.

For example, as shown in FIG. 1, a general organic TFT is constructed in such a manner that a gate electrode 20 is formed on a substrate 10 made of glass or the like and the upper part of the gate electrode 20 is covered with an insulating film 30 (a gate insulating film), and after that, a source electrode and a drain electrode are formed by a patterned wiring line 40 and an organic semiconductor layer 50 is provided between the two electrodes. By changing a voltage applied to the gate electrode, the quantity of electric charge at an interface between the gate insulating film and the organic semiconductor layer is made excessive or insufficient, whereby the current flowing across the source electrode/the organic semiconductor/the drain electrode (the drain current Id) is changed in order to perform switching.

As organic semiconductor materials used in such organic TFTs, there are known, for example, high molecular compound based materials, such as electrically conductive polymers and conjugated polymers, and low molecular compound based materials, such as aromatic or chained compounds of π-electron conjugated type, organic pigments and organic silicon compounds. However, both types of high molecular compound based materials and low molecular compound based materials have a general tendency to be easily oxidized. When the oxygen in the air is doped in an organic semiconductor layer, the carrier density increases and it becomes impossible to obtain stable characteristics because of an increase in leakage current and a change in mobility. Therefore, this posed the problem that stable characteristics cannot be obtained. Furthermore, some organic semiconductor materials had the problem that the moisture in the air reduces electrical conductivity and deteriorates other characteristics.

A structure in which on an organic TFT, a coating of polyvinyl alcohol (PVA) is used as a protective film is described in J. C. Ho et al., “NT-LCD Driven by Organic Thin-Film Transistor Arrays Fabricated by Printed Methods.” Proceedings of IDW' 03 (December, 2003). FIG. 1 shows a structure in which a protective film as disclosed in J. C. Ho et al. is provided for a circuit that uses an organic semiconductor as described above. In FIG. 1, on an organic semiconductor layer 50, there is formed a protective film 60 that covers the whole circuit element so as to be in contact with the organic semiconductor component 50.

However, as shown in FIG. 1, in the case where an organic semiconductor is directly coated with a protective film, there was a possibility that the problem that in the coating process, the organic semiconductor may suffer a damage or contamination with impurities, which are followed by deterioration in the characteristics of the organic semiconductor.

### SUMMARY OF THE INVENTION

An object of the present invention is, therefore, to provide an improved element structure which can solve the problems in the prior arts, and a method for manufacturing the same. Another object of the present invention is to provide a circuit element using an organic semiconductor that maintains the characteristics of organic semiconductors in a stable manner for a long period, is highly durable against various kinds of stresses, impacts, etc. from the outside and has excellent reliability, and a method of manufacturing the circuit element.

To solve the above problems, in the first aspect of the present invention, there is provided a circuit element that comprises a circuit portion including an organic semiconductor formed on a substrate and a sealing can which envelopes the circuit portion with a prescribed space.

In the second aspect of the present invention, there is shown the circuit element in which a circuit portion including an organic semiconductor and a structural portion of an organic EL element are provided on the substrate and the sealing can envelopes both of the circuit portion and the structural portion of an organic EL element with a prescribed space.

In the third aspect of the present invention, there is shown the circuit element in which the sealing can is made of glass, metal or ceramics.

In the fourth aspect of the present invention, there is shown the circuit element in which the circuit portion including an organic semiconductor is one of an organic transistor, an organic diode, an organic solar cell or an organic memory.

To solve the above problems, in the fifth aspect of the present invention, there is provided a method of manufacturing the circuit element, in which an organic semiconductor layer formed on a substrate undergoes sealing with the sealing can without exposing the organic semiconductor to the atomospheric gas or air.

### BRIEF DESCRIPTION OF THE DRAWINGS

FIG. 1 is a schematic sectional view that shows an example of the construction of a conventional circuit element;

FIGS. 2A to 2C are each a schematic sectional view that shows an example of the construction of a circuit element according to the present invention; and

FIG. 3 is a schematic sectional view that shows another example of the construction of a circuit element according to the present invention.

### DETAILED DESCRIPTION OF THE PREFERRED EMBODIMENTS

The present invention will be described in detail with reference to the accompanying drawings.

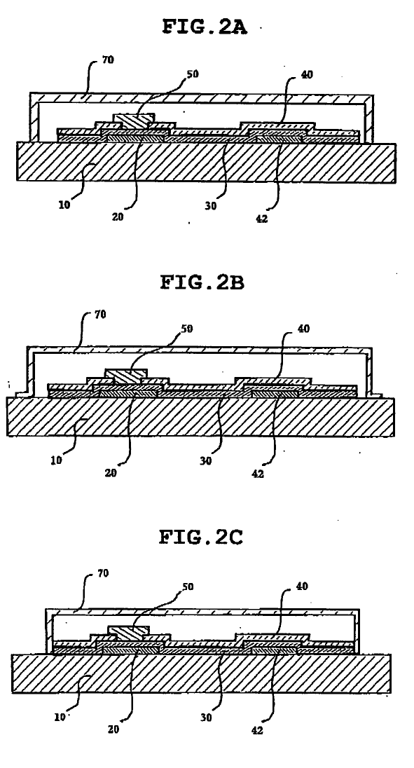

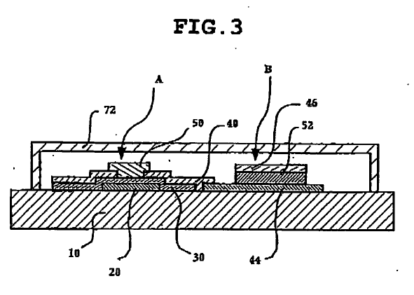

FIGS. 2A to 2C are each a sectional view that schematically shows an example of the construction of a circuit element according to the present invention, and FIG. 3 is a sectional view that schematic shows another example of the construction of a circuit element according to the present invention. Incidentally, in FIGS. 2 and 3, the thickness of each member is drawn in an exaggerated manner for the purpose of the illustration.

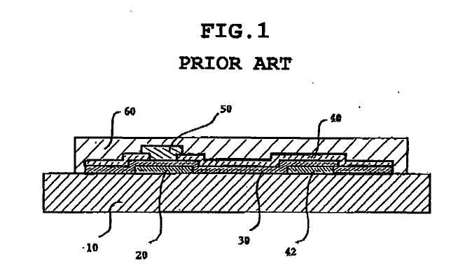

In the examples of structures shown in FIGS. 2A to 2C, as in the example of a conventional technique shown in FIG. 1, a gate electrode 20 is formed on a substrate 10 and the upper part of the gate electrode 20 is covered with an insulating film 30 (a gate insulating film), and after that, a source electrode and a drain electrode are formed by a patterned wiring line 40 and an organic semiconductor layer 50 is provided between the two electrodes. In the examples, on the lateral side of the above-described organic TFT structure, another wiring line 42 is formed on the substrate 1, and a circuit is formed by this wiring line 42 together with the wiring line 40, which is insulated by the insulating film 30.

In this circuit element, by changing a voltage applied to the gate electrode, the quantity of electric charge at an interface between the gate insulating film and the organic semiconductor layer is made excessive or insufficient, whereby the current flowing across the source electrode/the organic semiconductor/the drain electrode (the drain current Id) is changed, and thus, switching of a semiconductor device (not shown) connected by the wiring lines 40 and 42 is performed.

In the circuit elements according to the present invention shown in FIGS. 2A to 2C, there is formed a sealing can 70, which envelopes the circuit portion that is formed on the substrate 1 and contains the organic semiconductors, and the sealing can 70 shields the circuit portion from the air.

In the present invention, as shown in FIGS. 2A to 2C, the circuit portion including the organic semiconductor is sealed by use of a can-like structure without coming into contact with the organic semiconductor. Therefore, unlike a case where there is provided a protective film that is in contact with an organic semiconductor as in the example of the conventional technique (see FIG. 1), the characteristics of the semiconductor are not impaired in the forming process of the circuit element. Furthermore, because the mechanical strength of a sealing can is higher than a protective film in thin film form, the circuit element has high durability against various kinds of stresses and impacts from outside. Thus, the circuit element is excellent in overall reliability.

Materials for the sealing can 70 used in the present invention are not especially limited so long as they have the barrier properties against moisture and gases such as oxygen. It is possible to form the sealing can 70 from, for example, glasses such as soda lime glass, particularly, dealkalized soda lime glass, borosilicate glass, and silica glass, metals such as stainless steel, Al, Cu or various kinds of alloys, and various kinds of ceramics such as alumina, zirconia and titania, etc. Furthermore, it is possible to use various kinds of sealing cans, for example, those constituted by multiple layers of heterogeneous materials, for example, those which the surface of the vitreous substrate as described above is coated with a metal film; those in which multiple layers made of heterogeneous materials or a homogeneous material are adhered to each other or spaced from each other with an appropriate distance; and the like. The wall thickness of the sealing can cannot be generically defined because the wall thickness may be varied by the material to be used. However, as an appropriate wall thickness of the sealing, a range of about 0.001 to 5 mm, preferably about 0.01 to 0.5 mm may be exemplified.

Furthermore, although the spacing between the sealing can 70 and the organic semiconductor 50 is not especially limited, it is appropriate that the spacing be for example about >0 to 0.5 mm.

The shape of the sealing can 70 is not especially limited so long as it is possible for the sealing can 70 to cover a circuit portion including an organic semiconductor, and it is possible to adopt sealing cans of various shapes in addition to a sealing can with a roughly π-shaped section as in FIG. 2A. For example, a sealing can having a flange on the surface that abuts against the substrate as shown in FIG. 2B and a sealing can having such a shape that the inner side surface of the sealing can is brought into close contact with the side surface of a circuit portion formed on the substrate are able to form sufficient joints even when the wall thickness of the sealing can is small. In addition, other various modifications are possible. They are, for example, sealing cans in which the shape of the upper surface has concavities and convexities or is curved according to the shape (level difference) of the enclosed circuit portion.

The adhering of such a sealing can 70 and the substrate 10, which differs depending on the material for the sealing can and the substrate, can be performed by use of, for example, acrylic, epoxy and other adhesives of the heat-hardening type, ultraviolet-curing type, electron radiation curing type and other types.

Furthermore, in order to remove the moisture remaining in the enclosing space sealed by the sealing can 70 or the moisture that may enter through jointing portions formed by the above-described adhesive, it is possible to provide, on the inner surface side of the sealing can 70, a desiccant in such a manner as not to come into contact with the above-described organic semiconductor layer. This desiccant is, for example, non-deliquescent hygroscopic inorganic compounds, such as alkali metal oxides, alkaline earth oxides, sulfates, metal halides and perchlorates, organic water-absorbing compounds, such as water-absorbing polymers and polyvinyl alcohols, physical adsorptive substances, such as active carbon and zeolite, etc.

In order to eliminate the oxygen etc. remaining in the enclosing space sealed with the sealing can 70, it is also possible to add an inert gas that does not deteriorate the organic semiconductor, such as nitrogen and argon, in this enclosing space. Furthermore, in order to eliminate the oxygen etc. remaining in the enclosing space sealed with the sealing can 70, it is also possible to add a liquid or a solid, such as resin, which does not deteriorate the organic semiconductor, in this enclosing space.

After the formation of a lamination circuit including an organic semiconductor 50 as described above on the substrate 10, this sealing can 70 is formed, for example, by causing a sealing can structure, which has been formed separately in a prescribed shape, to adhere to the substrate 10 with an adhesive as described above. Preferably, after the formation of a layer of an organic semiconductor on the substrate, the sealing can 70 should be adhered to the substrate 10 without exposing the organic semiconductor to the air, in order to obtain a circuit element having better characteristics.

Next, in the example of a structure shown in FIG. 3, a circuit portion A including a thin-film transistor that uses an organic semiconductor 50 and a structural portion B of an organic EL element are formed on a substrate 10. In the example of a structure shown in FIG. 3, like the examples shown in FIGS. 2A to 2C above, the circuit portion A is constructed in such a manner that a gate electrode 20 is formed on the substrate 10 and the upper part of the gate electrode 20 is covered with an insulating film 30 (a gate insulating film), and after that, a source electrode and a drain electrode are formed by a patterned wiring line 40 and an organic semiconductor layer 50 is provided between the two electrodes. On the other hand, the structural portion B of an organic EL element that is provided in a side of the circuit portion A includes at least a first electrode layer of organic EL 44, an organic emitter layer 52 and a second electrode layer of organic EL 46 that are laminated in this order on the substrate 10. The structural portion B of an organic EL element is switching controlled by the above-described circuit that is electrically connected thereto.

In the example of a structure shown in FIG. 3, the circuit portion A including the organic semiconductor layer 50, along with the structural portion B of an organic EL element including the organic emitter layer 52, is enveloped by a sealing can 72 with a prescribed space. For this reason, there is no possibility that the organic semiconductor layer 50 and the organic emitter layer 52 may be exposed to the moisture and gases such as oxygen contained in the external atmosphere, and the circuit element can exhibit its desired characteristics for along period. Also, as described above, the mechanical strength of the sealing can is good and, therefore, the circuit element has high durability against various kinds of stresses and impacts from the outside. Thus, the circuit element is excellent in overall reliability.

Incidentally, the material, wall thickness, forming method and the like of the sealing can 72 in the example of structure shown in FIG. 3 are the same as described above for the examples shown in FIGS. 2A to 2C, and the same applies also to the adhesive used to bond the sealing can 72 to the substrate, the desiccant capable of being provided in the internal space, the sealing of an insert gas, etc. When in FIG. 3 the light emission direction of the organic EL element is the direction reverse to the substrate 10, i.e., in the case of what is called a “top emission structure” or when the light emission directions are two directions of the direction of the substrate 10 and the direction reverse to the substrate 10, i.e., in the case of a “dual emission structure”, it is necessary to use a transparent material as the material for the sealing can. If the bonding of the sealing can 72 to the substrate 10 is continuously performed in a closed system without exposing the organic semiconductor layer and the organic emitter of the organic EL element to the air after the formation thereof, it is possible to obtain a circuit element having better characteristics. Therefore, this is preferable.

In the examples of structures shown in FIGS. 2A to 2C and FIG. 3, materials for the substrate 10, gate electrode 20, wiring lines 40, 42, insulating film 30 and semiconductor component 50 are not especially limited and various kinds of known materials can be used.

For example, both high molecular compound based materials and low molecular compound based materials can be used as materials for the organic semiconductor. Low molecular compound based materials are, for example, aromatic or chained compounds of π-electron conjugated type, organic pigments and organic silicon compounds; concretely, they are, for example, pentacene, tetracene, phenelene derivatives, phthalocyanine compounds, benzodithiophene, fullerene, buckminsterfullerene, tetracyanonaphthoquinone, tertakis methyl aminoethylene, cyanine pigments, etc. However, low molecular compound based materials are not limited to them. High molecular compound based materials are, for example, electrically conductive polymers and conjugated polymers; concretely, they are, for example, polythiophene, poly(3-alkyl)thiophene, alkyl-substituted oligothiophene, polythienylene vinylene, poly(paraphenylene vinylene), polyacetylene derivatives, α-hexa thienylene oligomer, etc. However, high molecular compound based materials are not limited to them.

Materials for the substrate 10 are, for example, quartz or glass plates, metal plates, metal foils, plastic films or sheets, etc. However, materials for the substrate 10 are not limited to them.

The gate electrode 20 can be formed, for example, from metals such as gold, platinum, chromium, palladium, aluminum, indium, molybdenum and nickel, alloys of these metals, other inorganic materials such as polysilicon, amorphous silicon, tinoxides, indiumoxides, indium-tinoxides (ITO); or organic materials such as polyaniline and polythiophene, and conductive inks, capable of being formed by any coating method. However, materials for the gate electrode 20 are not limited to them.

The insulating film 30 can be made, for example, from inorganic materials such as silicon oxide, silicon nitride and aluminum oxide; or organic materials capable of being formed by using any coating method, such as polychrolpyrene, polyethylene terephthalate, polyoxy methylene, polyvinyl chloride, polyfluorovinylidene, cyanoethyl pullulan, polymethyl methacrylate, polysulfone, polycarbonate and polyimide. However, materials for the insulating film 30 are not limited to them.

For materials for the wiring line 40 that constitutes the source electrode and the drain electrode, in view of the fact that organic semiconductors are generally p-type semiconductors, metals such as gold and platinum having large values of work function can be used in order to ensure ohmic contact with an organic semiconductor layer. However, materials for the wiring line 40 are not limited to them. Incidentally, the “ohmic function” is a potential difference necessary for taking out the electrons of a solid to outside and defined as a value obtained by dividing an energy difference between a vacuum level and the Fermi level by the quantity of electric charge. In a case where the surface of an organic semiconductor layer is doped with a dopant at a high level, the tunneling of a carrier between the metal and the semiconductor becomes possible, and the dependency on the kinds of metals becomes small. In this case, therefore, the wiring line 40 can be formed from the various kinds of metal materials and organic materials as enumerated in connection with the above-described gate electrode.

In the circuit element according to the present invention, the circuit structure and lamination structure are not limited to the examples of a structure shown in FIGS. 2A to 2C and FIG. 3, and it is possible to adopt various types so long as they use at least an organic semiconductor. For example, in addition to organic TFTs as shown in FIGS. 2A to 2C and FIG. 3, it is possible to use an organic diode, an organic solar cell, an organic memory, etc.

Furthermore, the structure of an organic EL element formed on the substrate is not limited to the example of a structure shown in FIG. 3 and various known structures can be adopted substitutively. For example, the organic light-emitting layer can be formed as a functionally divided type in which the organic light-emitting layer is divided into a hole transportation layer and an electron transportation layer to improve the luminous efficiency, as a substitute for the single-layer type as shown in FIG. 3. Also, it is possible to adopt a structure in which an electron injection layer is provided between a light-emitting layer and a second electrode, a structure in which both a hole transportation layer and an electron transportation layer are provided, or a structure in which a hole transportation layer is mixed with a light-emitting layer, etc.

In a case where a plastic substrate or the like is used as the substrate, in order to prevent the entry of moisture, oxygen gas, etc. from the substrate side, a barrier film can be provided between the substrate 10 and a laminated circuit or a structure of an organic EL substrate as described above.

In the manufacture of the circuit element according to the present invention, the formation of each layer and patterning can be performed by using conventionally known techniques. For example, the coating methods such as the spin coating process, the vacuum deposition method and the like are used in the formation of organic layers including the organic semiconductor layer etc., the plasma CVD method and the like are used in the formation of the organic insulating film etc., and the sputtering method, the vacuum deposition method and the like are used in the formation of the metal film, tin oxides, indium oxide, ITO etc. Furthermore, for patterning, it is possible to use the patterning method using electron beams as well as a combination of known photolithography and dry etching or wet etching.

The present invention may be embodied in other specific forms without departing from the spirit or essential characteristics thereof. The present embodiments and examples are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosures of Japanese Patent Application No. 2004-87542 filed on Mar. 24, 2004 including the specification, claims, drawings and summaries are incorporated herein by reference in its entirety.

What is claimed is:

1. A circuit element comprising:
a circuit portion including an organic semiconductor formed on a substrate, and
a sealing can that envelopes the circuit portion with a prescribed space.

2. The circuit element according to claim 1, wherein said circuit element further comprises a structural portion of an organic EL element provided on the substrate in addition to the circuit portion; and the sealing can envelopes both of the circuit portion and the structural portion of an organic EL element with a prescribed space.

3. The circuit element according to claim 1, wherein the sealing can is made of glass, metal or ceramics.

4. The circuit element according to claim 2, wherein the sealing can is made of glass, metal or ceramics.

5. The circuit element according to claim 1, wherein the circuit portion including an organic semiconductor is one of an organic transistor, an organic diode, an organic solar cell or an organic memory.

6. The circuit element according to claim 2, wherein the circuit portion including an organic semiconductor is one of an organic transistor, an organic diode, an organic solar cell or an organic memory.

7. A method of manufacturing the circuit element, comprising:
making a circuit portion including an organic semiconductor layer and on a substrate, and then,
sealing the organic semiconductor layer with a sealing can without exposing the organic semiconductor to the atomospheric gas, the sealing enveloping the organic semiconductor layer with a prescribed space.

8. A method of manufacturing the circuit element according to claim 5, comprising:
making a structural portion of an organic EL element on a substrate, in addition to the circuit portion including the organic semiconductor layer, and then,
sealing the organic semiconductor layer and the organic EL element with the sealing can without exposing the organic semiconductor and the organic EL element to the atomospheric gas, the sealing enveloping the organic semiconductor layer and the structural portion of the organic EL element with a prescribed space.
